(19) United States
(12) Patent Application Publication
(10) Pub. No.: US 2023/0395724 A1
(43) Pub. Date: Dec. 7, 2023

(54) SEMICONDUCTOR DEVICE

(71) Applicant: Japan Display Inc., Tokyo (JP)

(72) Inventor: Akihiro HANADA, Tokyo (JP)

(73) Assignee: Japan Display Inc., Tokyo (JP)

(21) Appl. No.: 18/318,748

(22) Filed: May 17, 2023

(30) Foreign Application Priority Data
Jun. 6, 2022 (JP) 2022-091667

(51) Int. Cl. H01L 29/786; H01L 29/423; G02F 1/1368

(52) U.S. Cl. CPC H01L 29/78633; H01L 29/78696; H01L 29/7869; H01L 29/42384; G02F 1/1368

(57) ABSTRACT

A transistor includes a gate line, a first gate insulating film, a semiconductor film, a pair of terminals, a second gate insulating film, and a second gate electrode. A part of the gate line functions as a first gate electrode. The first gate insulating film is located over the first gate electrode. The semiconductor film is located over the first gate insulating film and overlaps the first gate electrode. The terminals are located over and electrically connected to the at least one semiconductor film. The second gate insulating film is located over the terminals. The second gate electrode has a light-transmitting property, is located over the second gate insulating film, overlaps the first gate electrode and the at least one semiconductor film, and is electrically connected to the first gate electrode through a first pair of openings formed in the first gate insulating film and the second gate insulating film.

### CROSS-REFERENCE TO RELATED APPLICATIONS

This application claims the benefit of priority to Japanese Patent Application No. 2022-091667, filed on Jun. 6, 2022, the entire contents of which are incorporated herein by reference.

### FIELD

An embodiment of the present invention relates to a semiconductor device. For example, an embodiment of the present invention relates to a semiconductor device capable of functioning as a display device.

### BACKGROUND

A semiconductor device exemplified by a display device is equipped with a transistor functioning as a switching element. For example, Japanese Patent Application Publication No. 2022-10017 discloses a semiconductor device mounted with a thin-film transistor having excellent electrical characteristics.

### SUMMARY

An embodiment of the present invention is a semiconductor device including a transistor. The transistor includes a gate line, a first gate insulating film, at least one semiconductor film, a pair of terminals, a second gate insulating film, and a second gate electrode. A part of the gate line functions as a first gate electrode. The first gate insulating film is located over the first gate electrode. The at least one semiconductor film is located over the first gate insulating film and overlaps the first gate electrode. The pair of terminals is located over and electrically connected to the at least one semiconductor film. The second gate insulating film is located over the pair of terminals. The second gate electrode has a light-shielding property, is located over the second gate insulating film, overlaps the first gate electrode and the at least one semiconductor film, and is electrically connected to the first gate electrode through a first pair of openings formed in the first gate insulating film and the second gate insulating film. The first pair of openings sandwich the at least one semiconductor film in one of a channel width direction and a channel length direction of the transistor. A length of the first pair of openings in the channel width direction is larger than a channel width of the transistor when the first pair of openings sandwich the at least one semiconductor film in the channel length direction. A length of the first pair of openings in the channel length direction is larger than a channel length of the transistor when the first pair of openings sandwich the at least one semiconductor film in the channel width direction.

### BRIEF DESCRIPTION OF DRAWINGS

FIG. 1A is a schematic top view of a semiconductor device according to an embodiment of the present invention.

FIG. 1B is a schematic top view of a semiconductor device according to an embodiment of the present invention.

FIG. 2A is a schematic cross-sectional view of a semiconductor device according to an embodiment of the present invention.

FIG. 2B is a schematic cross-sectional view of a semiconductor device according to an embodiment of the present invention.

FIG. 2C is a schematic cross-sectional view of a semiconductor device according to an embodiment of the present invention.

FIG. 2D is a schematic cross-sectional view of a semiconductor device according to an embodiment of the present invention.

FIG. 3 is an example of equivalent circuits of a pixel circuit provided in a pixel of a semiconductor device according to an embodiment of the present invention.

FIG. 4 is a schematic top view of a pixel of a semiconductor device according to an embodiment of the present invention.

FIG. 5A is a schematic cross-sectional view of a pixel of a semiconductor device according to an embodiment of the present invention.

FIG. 5B is a schematic top view of a pixel of a semiconductor device according to an embodiment of the present invention.

FIG. 6 is a schematic cross-sectional view of a pixel of a semiconductor device according to an embodiment of the present invention.

FIG. 7 is a schematic top view of a pixel of a semiconductor device according to an embodiment of the present invention.

FIG. 8 is a schematic cross-sectional view of a pixel of a semiconductor device according to an embodiment of the present invention.

FIG. 9 is a schematic top view of a pixel of a semiconductor device according to an embodiment of the present invention.

FIG. 10A is a schematic cross-sectional view of a pixel of a semiconductor device according to an embodiment of the present invention.

FIG. 10B is a schematic top view of a pixel of a semiconductor device according to an embodiment of the present invention.

FIG. 11 is a schematic cross-sectional view of a pixel of a semiconductor device according to an embodiment of the present invention.

FIG. 12 is a schematic top view of a pixel of a semiconductor device according to an embodiment of the present invention.

FIG. 13A is a schematic cross-sectional view of a pixel of a semiconductor device according to an embodiment of the present invention.

FIG. 13B is a schematic top view of a pixel of a semiconductor device according to an embodiment of the present invention.

FIG. 14 is a schematic cross-sectional view of a pixel of a semiconductor device according to an embodiment of the present invention.

FIG. 15 is a schematic top view of a pixel of a semiconductor device according to an embodiment of the present invention.

FIG. 16A is a schematic cross-sectional view of a pixel of a semiconductor device according to an embodiment of the present invention.

FIG. 16B is a schematic top view of a pixel of a semiconductor device according to an embodiment of the present invention.

FIG. 17 is a schematic cross-sectional view of a pixel of a semiconductor device according to an embodiment of the present invention.

FIG. 18 is a schematic top view of a pixel of a semiconductor device according to an embodiment of the present invention.

FIG. 19A is a schematic cross-sectional view of a pixel of a semiconductor device according to an embodiment of the present invention.

FIG. 19B is a schematic top view of a pixel of a semiconductor device according to an embodiment of the present invention.

FIG. 20 is a schematic cross-sectional view of a pixel of a semiconductor device according to an embodiment of the present invention.

FIG. 21 is a schematic top view of a pixel of a semiconductor device according to an embodiment of the present invention.

FIG. 22 is a schematic top view of a pixel of a semiconductor device according to an embodiment of the present invention.

FIG. 23A is a schematic top view of a pixel of a semiconductor device according to an embodiment of the present invention.

FIG. 23B is a schematic top view of a pixel of a semiconductor device according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

In the embodiments of the present invention, when a plurality of films is formed with the same process at the same time, these films have the same layer structure, the same material, and the same composition. Hence, the plurality of films is defined as existing in the same layer.

Hereinafter, a semiconductor device 100, which is an embodiment of the present invention is explained. Here, an embodiment is explained using a mode as an example in which the semiconductor device 100 is a liquid crystal display device. However, the semiconductor device 100 is not limited to a liquid crystal display device, and may also be an organic electroluminescence device, an electronic paper type display device having an electrophoretic element, or the like. Alternatively, the semiconductor device 100 may be a photoelectric conversion device such as a solar cell and an imaging device or a memory device.

### 1. OUTLINE STRUCTURE

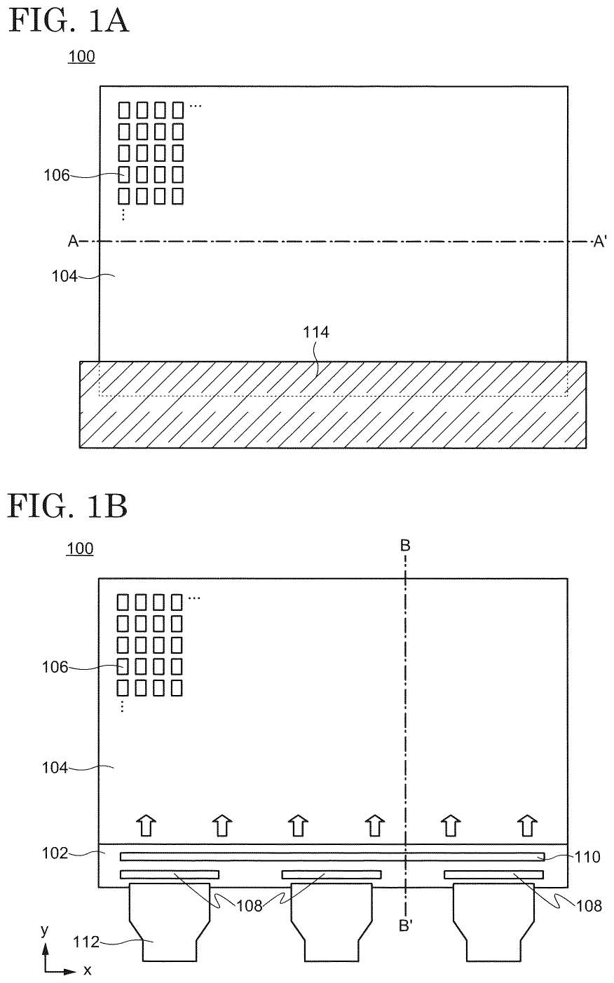

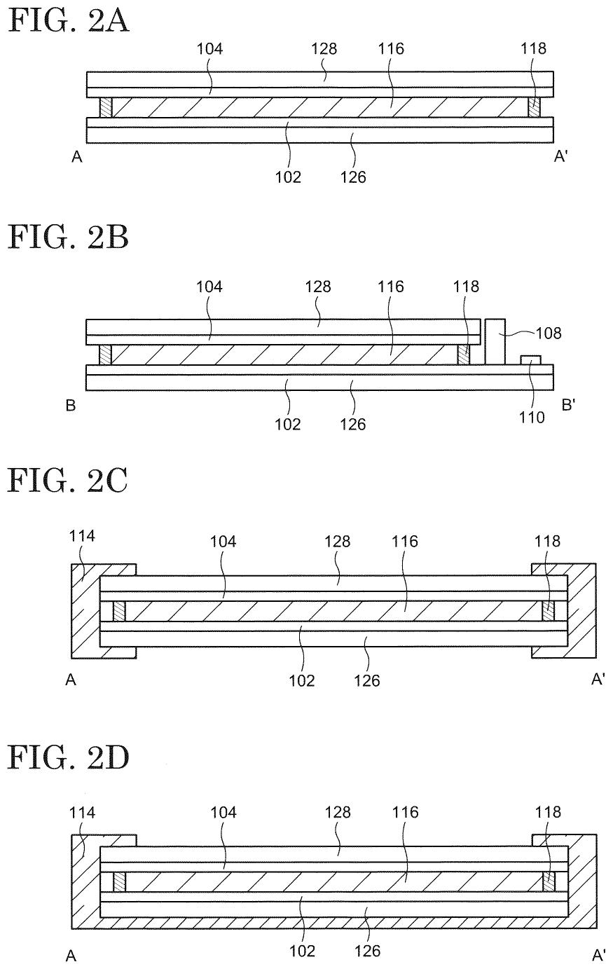

Schematic top views of the semiconductor device 100 functioning as a liquid crystal display device are shown in FIG. 1A and FIG. 1B. As shown in these drawings, the semiconductor device 100 has a pair of substrates (substrate 102 and counter substrate 104). The substrate 102 and the counter substrate 104 are glass substrates, and a first transparent substrate 126 and a second transparent substrate 128 each containing glass are provided under the substrate 102 and over the counter substrate 104, respectively. The first transparent substrate 126 and the second transparent substrate 128 are also referred to as cover glass. Note that the first transparent substrate 126 can be recognized as a part of the substrate 102, and similarly, the second transparent substrate 128 can be recognized as a part of the counter substrate 104. A variety of patterned insulating films, conductive films, and semiconductor films is stacked between the substrate 102 and the counter substrate 104, by which a plurality of pixels 106 is formed. The counter substrate 104 is smaller than the substrate 102, and a part of the substrate 102 is exposed from the counter substrate 104. As shown in schematic drawings of the cross sections along chain lines A-A′ and B-B′ in FIG. 1A (FIG. 2A and FIG. 2B), the substrate 102 and the counter substrate 104 are adhered to each other by a sealing material 118, and a liquid crystal layer 116 is provided in a space formed by the substrate 102, the counter substrate 104, and the sealing material 118.

In an area where the substrate 102 is exposed from the counter substrate 104, a light source 110 fabricated by arranging a plurality of red-emissive light-emitting elements, a plurality of green-emissive light-emitting elements, and a plurality of blue-emissive light-emitting elements, which are not illustrated, is arranged so as to be exposed from the counter substrate 104 (FIG. 1B and FIG. 2B). These light-emitting elements are driven in a field sequential manner. The light-emitting elements provided in the light source 110 are arranged so that light travels in a direction toward the plurality of pixels 106, i.e., a direction parallel to main surfaces of the substrate 102 and the counter substrate 104 (see hollow arrows in FIG. 1B). More specifically, the light source 110 is configured to irradiate the second transparent substrate 128 and/or the counter substrate 104 with light.

Driver circuits 108 are further provided over the substrate 102 to drive the pixels 106. The driver circuits 108 may be composed of an IC chip fabricated by forming an integrated circuit over a semiconductor substrate or may fabricated by a laminate of a variety of insulating films, conductive films and semiconductor films patterned over the substrate 102. In the former case, the driver circuits 108 are mounted over a part of the substrate 102 exposed from the counter substrate 104. In the latter case, the driver circuits 108 are preferred to be provided on the pixel 106 side than the light source 110 so as to be covered by the counter substrate 104.

A variety of wirings, which is not illustrated, is further formed over the substrate 102, by which the plurality of pixels 106 is connected to the driver circuits 108 and the driver circuits 108 are electrically connected to connectors 112 such as flexible printed circuit (FPC) boards. Power and a variety of signals are input to the driver circuits 108 from an external circuit, which is not illustrated, via the connectors 112. The driver circuits 108 generate control signals to control the pixels 106 on the basis of the input signals. The control signals include gate signals, initialization signals, video signals, and the like. The pixel 106 is the smallest unit providing color information, and the orientation of the liquid crystal layer 116 overlapping the pixels 106 is controlled by controlling the pixels 106 with the control signals, thereby controlling the transmittance of the liquid crystal layer 116. By this mechanism, the gradation of light obtained from the light source 110 through the pixels 106 is controlled allowing the semiconductor device 100 to display images on the basis of the video signals.

As shown in FIG. 1A, at least a part of the substrate 102 and the counter substrate 104 is accommodated in a housing 114. As can be understood from FIG. 1A and FIG. 1B, the light source 110, the driver circuits 108, and the connectors 112 are also accommodated in the housing 114. Since the light source 110, the driver circuits 108, and the connector 112 can be covered by using the housing 114 which does not transmit visible light, the semiconductor device 100 with a high design quality can be produced. Note that the housing 114 may be configured to accommodate only the sides of the substrate 102 and the counter substrate 104 on which the connectors 112 are provided and a part of two sides connected to each of these sides as shown in FIG. 1A or to accommodate all of the sides of the substrate 102 and the counter substrate 104 as shown in FIG. 2C. In addition, the housing 114 may be configured so as not to overlap all of the pixels 106 to allow the image to be visible from both the substrate 102 side and the counter substrate 104 side as shown in FIG. 1A. Alternatively, the housing 114 may be configured so as to cover the whole of a bottom side of the substrate 102 (a surface on the opposite side to the counter substrate 104) or an upper surface of the counter substrate 104 (a surface on the opposite side to the substrate 102) as shown in FIG. 2D. The use of the former configuration allows the fabrication of the so-called transparent display device. On the other hand, since the images can be viewed only through one of the substrate 102 and the counter substrate 104 by adopting the latter configuration, not only can light from the light source 110 be effectively utilized, but also a semiconductor device suitable for wall-side installation can be provided.

### 2. STRUCTURE OF PIXEL

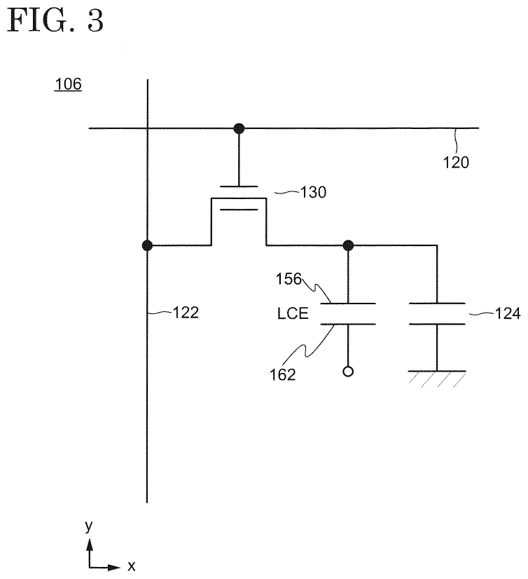

A pixel circuit is formed in each pixel 106. An example of the pixel circuit in one pixel 106 is shown in FIG. 3 as an equivalent circuit. In this example, one transistor 130 and one capacitor element 124 are provided in addition to a liquid crystal element LCE in each pixel 106, and the liquid crystal element LCE is controlled by the transistor 130 and capacitor element 124. However, the configuration of the pixel circuit may be arbitrarily determined, and the pixel circuit may be configured using a plurality of transistors and capacitance elements.

A plurality of gate lines 120 and signal lines 122 extend from the driver circuits 108 and intersect each other. Although the directions in which the gate lines 120 and signal lines 122 extend may be set arbitrarily, the following explanation is provided using a configuration as an example in which the gate lines 120 are arranged parallel to the side on which the light source 110 and the driver circuits 108 are provided (a side parallel to the direction in which the light source 110 extends or to the arrangement direction of the plurality of light-emitting elements in the light source 110). Thus, in the following explanation, unless otherwise noted, the gate lines 120 and the signal lines 122 extend in a x direction and y direction, respectively, which intersect each other, as shown in FIG. 1B and FIG. 3. The light from the light source 110 travels mainly in the y direction.

Each pixel circuit is connected to the corresponding gate line 120 and signal line 122. The turning on and off of the transistor 130 is controlled by the gate signal supplied to the gate line 120, and potentials based on the initialization signal and the video signal are supplied via the signal line 122 when the transistor 130 is on, by which the potential of a pixel electrode 156 of the liquid crystal element LCE electrically connected to the transistor 130 is controlled. The capacitor element 124 is provided to hold the potential of the pixel electrode 156. Since a constant potential is supplied to the other electrode (common electrode) 162 of the liquid crystal element LCE, the orientation of liquid crystal molecules in the liquid crystal layer overlapping the pixel electrodes 156 is controlled by the potential difference between the pixel electrodes 156 and the common electrode 162.

### 3. TRANSISTOR

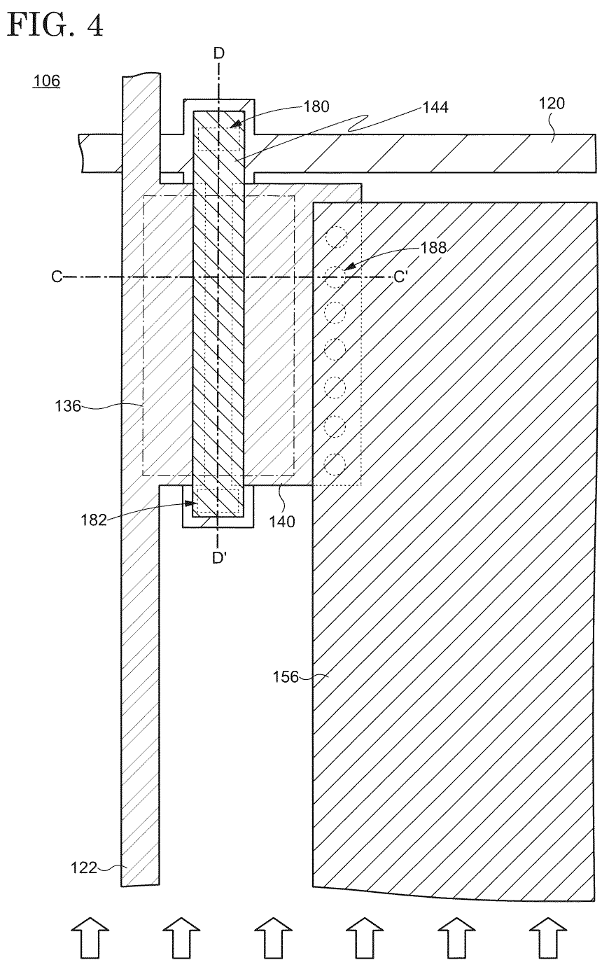

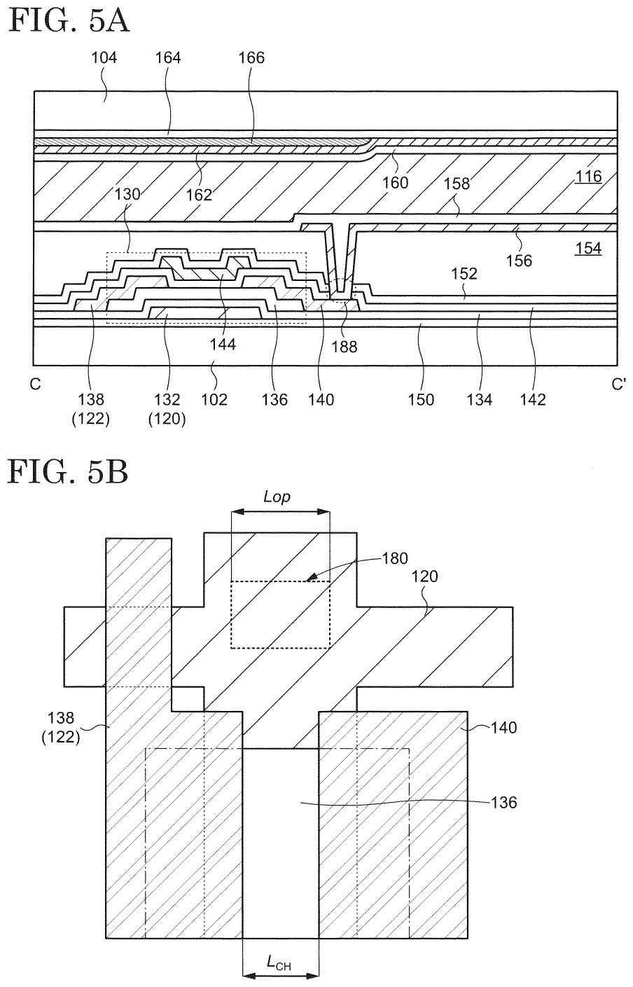

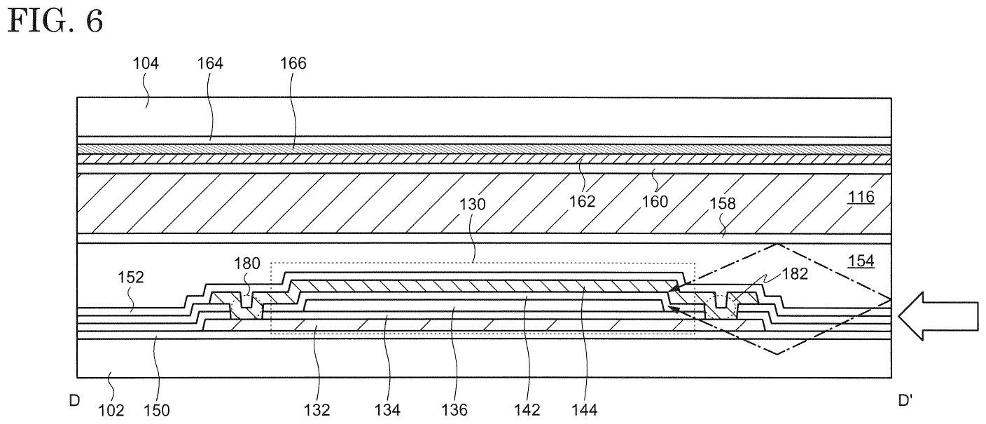

A schematic view of the top surface of a part of the pixel 106 of the semiconductor device 100 is shown in FIG. 4, and schematic views of cross sections along chain lines C-C′ and D-D′ in FIG. 4 are shown in FIG. 5A and FIG. 6, respectively. As can be understood from these drawings, the transistor 130 includes a first gate electrode 132, a first gate insulating film 134, at least one semiconductor film 136, a pair of terminals 138 and 140, a second gate insulating film 142, and a second gate electrode 144.

The first gate electrode 132 is a part of the gate line 120, in other words, a part of the gate line 120 functions as the first gate electrode 132. The first gate electrode 132 is formed over the substrate 102 directly or through an undercoat 150. In the former case, the gate line 120 and the first gate electrode 132 are directly formed over the substrate 102. The undercoat 150 is provided to prevent impurities such as metal ions contained in the substrate 102 from infiltrating the transistor 130 and composed of one or more films containing a silicon-containing inorganic compound such as silicon nitride and silicon oxide. The first gate electrode 132 is configured to block light, particularly visible light, so that light from the light source 110 is not applied onto the semiconductor film 136. More specifically, the first gate electrode 132 includes a metal such as tungsten, molybdenum, titanium, tantalum, aluminum, and copper or an alloy including one or more of these metals and is formed to have a thickness (e.g., equal to or more than 20 nm and equal to or less than 1000 nm) capable of blocking visible light. The first gate electrode 132 may be formed using a sputtering method, a chemical vapor deposition (CVD) method, or the like.

The first gate insulating film 134 is located over the first gate electrode 132 to cover the first gate electrode 132. The first gate insulating film 134 may be composed of one or more films including a silicon-containing inorganic compound such as silicon oxide or silicon nitride or an inorganic insulator having a high dielectric constant such as hafnium silicate, zirconium silicate, hafnium oxide, and zirconium oxide. The first gate insulating film 134 may also be formed using a sputtering method, a CVD method, or the like.

The semiconductor film 136 forms a channel of the transistor 130. Note that, in this specification, the channel refers to the portion of the semiconductor film 136 which overlaps both the first gate electrode 132 and the second gate electrode 144 and is exposed from the pair of terminals 138 and 140. The semiconductor film 136 is provided over the first gate insulating film 134 and is arranged to overlap the first gate electrode 132. The semiconductor film 136 may be a crystalline, amorphous, or microcrystalline film containing a group 14 element such as silicon and germanium or a crystalline, amorphous, or microcrystalline oxide semiconductor film. Oxide semiconductors include mixed oxides of group 13 elements such as indium-gallium oxide (IGO). The oxide semiconductors may further contain a group 12 element. As a typical oxide semiconductor containing a group 12 element, indium-gallium-zinc oxide (IGZO) is represented. The semiconductor film 136 containing an oxide semiconductor may further contain other elements and may include a group 14 element such as tin or a group 4 element such as titanium and zirconium. The semiconductor film 136 containing silicon or germanium is formed using a CVD method, for example. On the other hand, the semiconductor film 136 containing an oxide semiconductor may be formed utilizing a sputtering method, for example.

When the semiconductor film 136 is an oxide semiconductor film, the first gate insulating film 134 is preferably configured as a single film containing silicon oxide or as a stack of a plurality of films such that the film in contact with the semiconductor film 136 contains silicon oxide. This configuration can suppress the entrance of impurities which can be a source of carrier generation, such as hydrogen, into the semiconductor film 136, and as a result, the generation of levels caused by impurities in the semiconductor film 136 can be prevented.

One terminal 138 is a part of the signal line 122 and is located over the semiconductor film 136 so as to be in contact with a part of the semiconductor film 136. The other terminal 140 is also located over the semiconductor film 136 and is disposed so as to be in contact with a part of the semiconductor film 136. The pair of terminals 138 and 140 exists in the same layer, where one functions as a source electrode and the other functions as a drain electrode. The pair of terminals 138 and 140 is also configured to block visible light. Thus, the pair of terminals 138 and 140 also includes the above-mentioned metal or alloy and may be formed using a sputtering method, a CVD method, or the like so as to have a thickness capable of blocking visible light.

The second gate insulating film 142 is provided over the pair of terminals 138 and 140 so as to cover the pair of terminals 138 and 140. The second gate insulating film 142 may also include the materials usable in the first gate insulating film 134. Similar to the first gate insulating film 134, the second gate insulating film 142 is also preferably configured as a single film containing silicon oxide or as a stack of a plurality of films such that the film in contact with the semiconductor film 136 contains silicon oxide when the semiconductor film 136 is an oxide semiconductor film.

The second gate electrode 144 is provided over the second gate insulating film 142 and overlaps the first gate electrode 132 and the semiconductor film 136. The second gate electrode 144 is also configured to block visible light. Accordingly, the second gate electrode 144 may also include the materials usable in the first gate electrode 132 and is formed using a sputtering method, a CVD method, or the like to have a thickness capable of blocking visible light.

Here, the second gate electrode 144 is electrically connected to the first gate electrode 132 through a pair of openings 180 and 182 formed in the first gate insulating film 134 and the second gate insulating film 142 as shown in FIG. 4 and FIG. 6. Hence, the first gate electrode 132 and the second gate electrode 144 are equipotential with each other, and the on and off of the transistor 130 is controlled by the potential applied to these electrodes. As shown in FIG. 4 and FIG. 6, the pair of openings 180 and 182 is provided to sandwich the semiconductor film 136 in the channel width direction of the transistor 130. An enlarged view of a part of FIG. 4 is shown in FIG. 5B. In FIG. 5B, the second gate electrode 144 is not illustrated for visibility. As can be understood from FIG. 4 and FIG. 5B, the length L_{OP} of each of the pair of openings 180 and 182 in the channel length direction (i.e., a direction parallel to the extending direction of the gate line 120) is greater than the channel length L_{CH} of the transistor 130. Furthermore, in the channel width direction, i.e., a direction in which the signal line 122 extends along the plurality of pixels 106, the whole of the channel of the transistor 130 is sandwiched by the pair of openings 180 and 182. Moreover, in the normal direction of the substrate 102, the whole of the channel of the transistor 130 overlaps the first gate electrode 132 (see FIG. 4) and the second gate electrode 144 (see FIG. 6) between the pair of openings 180 and 182. Similarly, in the channel width direction, the pair of terminals 138 and 140 is sandwiched between the pair of openings 180 and 182. Note that the pair of openings 180 and 182 may be formed so as to sandwich the whole of the semiconductor film 136 in the channel width direction or sandwich a part of the semiconductor film 136.

Electrical properties of transistors may change when the channel is irradiated with light. In particular, properties of transistors having an oxide semiconductor in a channel readily degrade when irradiated with light, resulting in a large shift of a threshold voltage. Although a light source is installed under a substrate as a backlight in conventional liquid crystal display devices, the channel is not directly irradiated with light because the light from the light source is blocked by a light-shielding film and a gate electrode provided between the light source and the channel. Thus, degradation of the properties of transistors caused by the light from the backlight can be almost negligible in the conventional liquid crystal display devices.

On the other hand, as described above, the light source 110 is provided over the substrate 102, and the light-emitting elements structuring the light source 110 radiate the light toward the pixels 106 in the direction parallel to the main surfaces of the substrate 102 and the counter substrate 104 in the semiconductor device 100 according to an embodiment of the present invention (see FIG. 1B and FIG. 2B). Therefore, since the majority component of the light from the light source 110 travels in the direction (y direction) in which the signal line 122 extends (see hollow arrows in FIG. 4) using the substrate 102, the counter substrate 104, the first transparent substrate 126, and the second transparent substrate 128 as the main light guide path, the light from the substrate 102 to the channel of the semiconductor film 136 can be blocked by the first gate electrode 132 while the light from the counter substrate 104 to the channel of the semiconductor film 136 cannot be blocked by the first gate electrode 132. However, the whole of the channel overlaps the second gate electrode 144 having light-shielding properties as described above. Hence, as demonstrated in FIG. 6, at the edge surface along the direction in which the light represented by the hollow arrow travels from the light source 110, the channel is confined by the first gate electrode 132 and the second gate electrode 144 so that the light is not applied to the channel. In addition, although a part of the light from the light source 110 may have components which are reflected within the semiconductor device 100 and diagonally travel with respect to the channel of the semiconductor film 136 as shown by the chain arrows in FIG. 6, these components are also blocked not only by the second gate electrode 144 but also by the first gate electrode 132 having light-shielding properties, thereby effectively shielding the channel from the light of the light source 110. Therefore, in the semiconductor device 100, photo-degradation of the transistor 130 is effectively suppressed. This means that implementation of an embodiment of the present invention enables the production of highly reliable semiconductor devices with extremely small characteristic change.

### 4. LIQUID CRYSTAL ELEMENT

As shown in FIG. 5A and FIG. 6, a planarization film 154 containing a polymer such as an epoxy resin, an acrylic resin, a polyimide, and a polysiloxane resin is provided over the transistor 130, by which the depressions and projections caused by the transistor 130 and the like are absorbed to form a flat surface. As an optional component, an interlayer film 152 including one or more films containing a silicon-containing inorganic compound may be provided between the transistor 130 and the planarization film 154. As shown in FIG. 4 and FIG. 5A, the pixel electrode 156 is provided over the upper surface of the planarization film 154. The pixel electrode 156 is electrically connected to the terminal 140 through one or a plurality of openings 188 formed in the interlayer film 152 and the planarization film 154, by which the potential applied to the signal line 122 can be supplied to the pixel electrode 156.

The pixel electrode 156 is formed of a conductive oxide such as indium-tin mixed oxide (ITO) and indium-zinc mixed oxide (IZO) to transmit the light from the light source 110. The pixel electrode 156 may also be formed by a sputtering method or the like.

A first orientation film 158 is provided over the pixel electrode 156. The first orientation film 158 includes a polymer such as a polyimide and a polyester. The first orientation film 158 is formed using an ink-jet method, a dip-coating method, a spin coating method, or the like, and its surface is then subjected to a rubbing treatment. Alternatively, the first orientation film 158 may be formed by photo-orientation. The photo-orientation is a rubbing-less orientation process using light. For example, after applying a photo-curable resin having mesogen groups, polarized light in the ultraviolet region is applied from a predetermined direction. This process causes a photoreaction in the photo-curable resin, resulting in cross-linking and fixing the orientation of the mesogen groups, thereby imparting anisotropy to the surface.

A light-shielding film 166 is formed over the counter substrate 104 (below the counter substrate 104 in FIG. 5A and FIG. 6. The same is applied below.) directly or through an undercoat 164. The undercoat 164 may have the same structure as the undercoat 150. The light-shielding film 166 includes a metallic material which has a low transmittance to visible light or does not substantially transmit visible light, and is provided so as to overlap the transistor 130, the gate line 120, the signal line 122, and the like. The opening portions of the light-shielding film 166 overlap the pixel electrodes 156.

The common electrode 162 is provided over the light-shielding film 166. The common electrode 162 is provided across the plurality of pixels 106. In the semiconductor device 100, one common electrode 162 may be provided to be shared by all of the pixels 106, or a plurality of common electrodes 162 may be provided each arranged in parallel to the gate lines 120 or the signal lines 122 and shared by the plurality of pixels 106. The structure of the common electrode 162 is similar to that of the pixel electrodes 156 and is formed to include a light-transmitting conductive oxide such as ITO and IZO. Therefore, the pixel electrode 156 and the common electrode 162 overlapping the pixel electrode 156, which occupy most of the area of the pixel 106, are capable of transmitting visible light. Therefore, the semiconductor device 100 functions as a transparent display device capable of transmitting visible light.

A second orientation film 160 is provided over the common electrode 162. Since the structure of the second orientation film 160 is also the same as that of the first orientation film 158, a detailed explanation is omitted. The first orientation film 158 and the second orientation film 160 control the initial orientation direction of the liquid crystal molecules included in the liquid crystal layer 116.

The liquid crystal layer 116 is disposed between the first orientation film 158 and the second orientation film 160. The liquid crystal element LCE is structured by the liquid crystal layer 116 in addition to the pixel electrode 156, the first orientation film 158, the second orientation film 160, and the common electrode 162 sandwiching the liquid crystal layer 116. Although not illustrated, a spacer may be provided in the liquid crystal layer 116 to maintain the distance between the substrate 102 and the counter substrate 104. Furthermore, a touch sensor may be provided over (a side opposite to the substrate 102) and/or below the substrate 104. Although the liquid crystal element LCE with the aforementioned structure is a so-called PDLC (Polymer Dispersed Liquid Cristal) element, the liquid crystal element LCE included in the semiconductor device 100 may be a TN (Twisted Nematic) liquid crystal element, an IPS (In-Plane Switching) liquid crystal element, or an FFS (Fringe Field Switching) liquid crystal element which is a sort of IPS.

### 5. MODIFIED EXAMPLES

Hereinafter, modified examples of the aforementioned semiconductor device 100 are described. The features shown in the following modified examples may be applied to the semiconductor device 100 described above as appropriate or may be combined with each other.

### (1) Modified Example 1

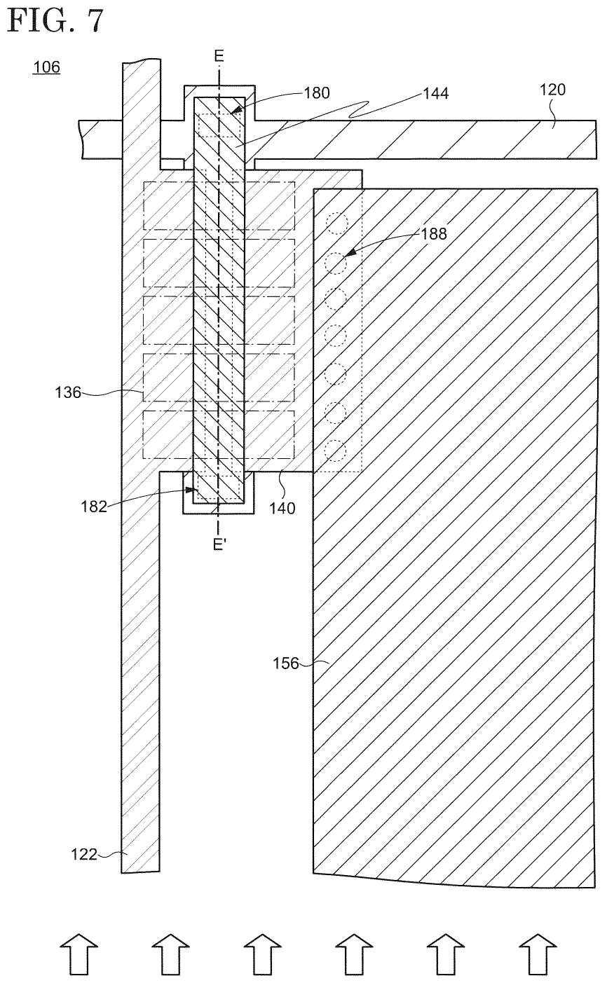

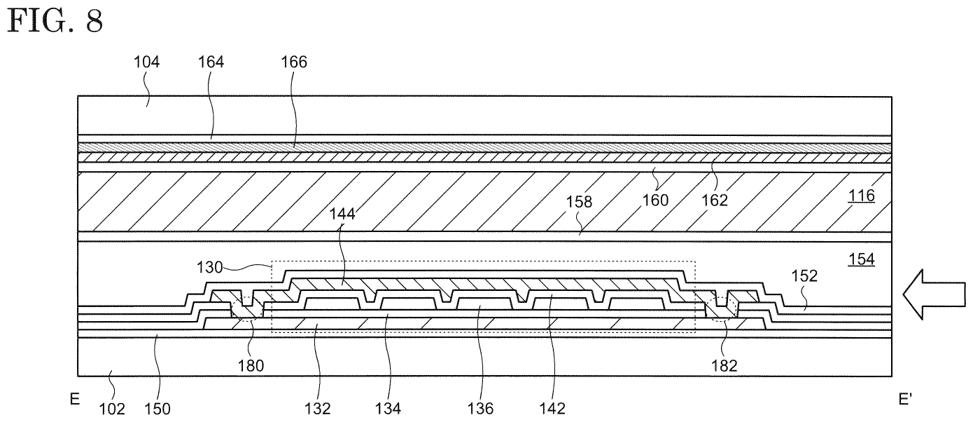

The structure of the transistor 130 provided in the semiconductor device 100 is not limited to the aforementioned structure and may be modified as appropriate. For example, as shown in a schematic top view of FIG. 7 and a schematic view of a cross section along a chain line E-E′ in FIG. 7 (FIG. 8), the at least one semiconductor film 136 may include a plurality of semiconductor films 136. In this case, the plurality of semiconductor films 136 is arranged so as to be aligned in the channel width direction. The channel of each semiconductor film 136 is entirely sandwiched between the pair of openings 180 and 182 in the channel width direction and overlaps the first gate electrode 132 and the second gate electrode 144 in the normal direction of the substrate 102 between the pair of openings 180 and 182. The transistor 130 is apparently composed of a plurality of transistors by structuring the transistor 130 with the plurality of semiconductor films 136. In other words, a plurality of channels is formed in the transistor 130. When current flows through a channel of a transistor, the amount of heat generated increases as a channel width increases with respect to the channel length, and degradation caused by the heat generation readily occurs. The formation of the plurality of semiconductor films 136 decreases the channel width with respect to the channel length in each channel, thereby suppressing degradation caused by the heat generation. Therefore, the transistor 130 of this modified example can be suitably used in semiconductor devices requiring a large current.

### (2) Modified Example 2

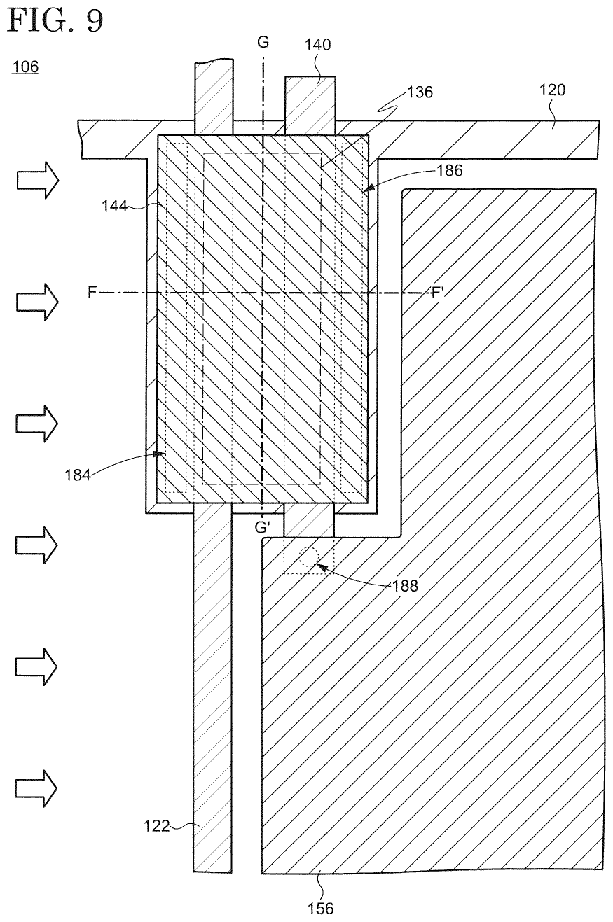

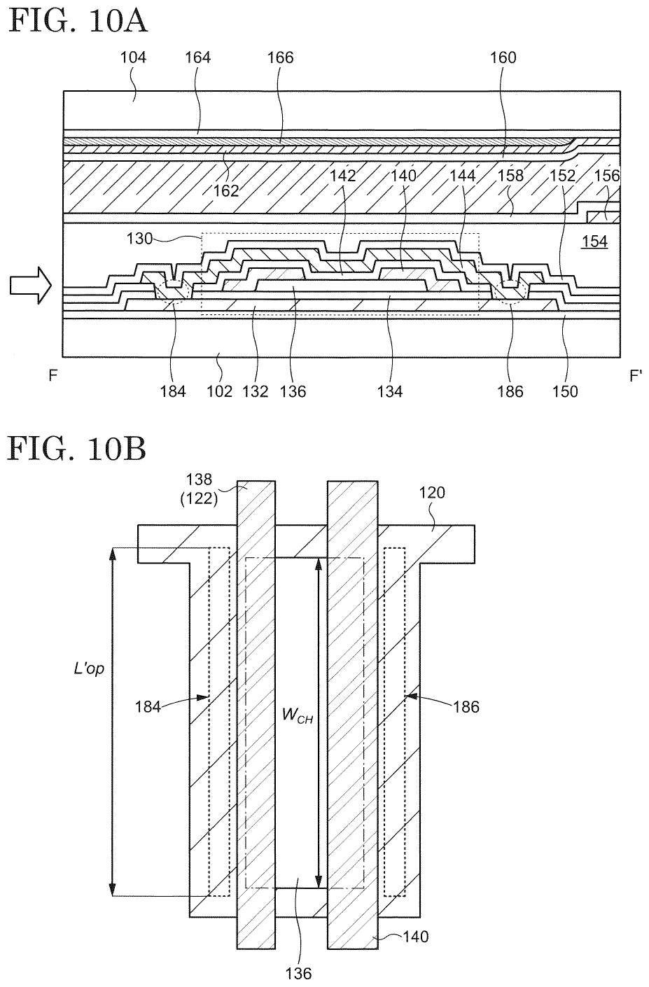

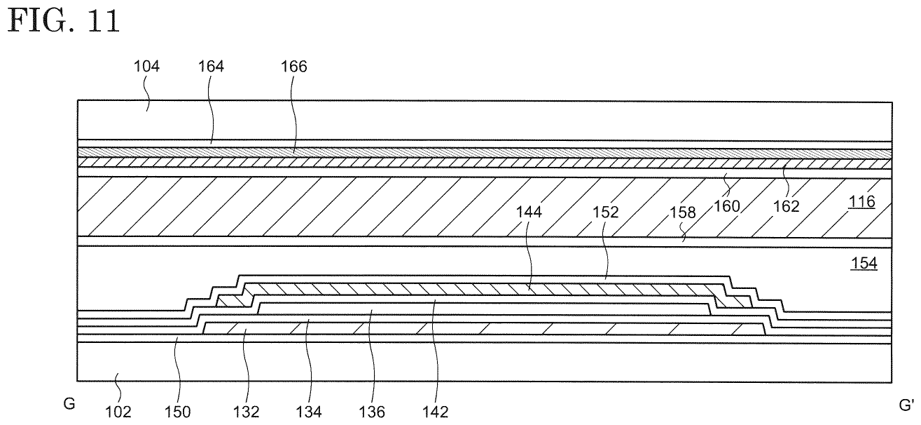

The semiconductor device 100 may be configured such that a pair of openings electrically connecting the first gate electrode 132 and the second gate electrode 144 sandwiches the channel in the channel length direction. A schematic top view of the semiconductor device 100 of the modified example 2 is shown in FIG. 9, and schematic views of cross sections along chain lines F-F′ and G-G′ in FIG. 9 are respectively shown in FIG. 10A and FIG. 11. As demonstrated in these drawings, openings 184 and 186 sandwiching the channel in the channel length direction may be formed in the first gate insulating film 134 and the second gate insulating film 142 in the semiconductor device 100. An enlarged view of a part of FIG. 9 is shown in FIG. 10B. In FIG. 10B, the second gate electrode 144 is not illustrated for visibility. As can be understood from FIG. 10B, a length L′_{OP} of each of the openings 184 and 186 in the channel width direction, i.e., the direction in which the signal line 122 extends, is larger than the channel width W_{CH} of the transistor 130. In the channel length direction, the whole of the channel of the transistor 130 is sandwiched between the pair of openings 184 and 186. At the same time, in the normal direction of the substrate 102, the whole of the channel of the transistor 130 overlaps the first gate electrode 132 and the second gate electrode 144 between the pair of openings 184 and 186 (see FIG. 11). In the channel length direction, the terminal 138 (or the signal line 122) and the terminal 140 are also sandwiched by the pair of openings 184 and 186 (see FIG. 9 and FIG. 10A).

Therefore, in this modified example, when the semiconductor device 100 is configured so that the light from the light emitting elements is applied toward the pixels 106 in the x direction (see hollow arrows in FIG. 9 and FIG. 10A), the light is blocked by the first gate electrode 132 and the second gate electrode 144 to prevent the semiconductor film 136 from being irradiated with the light. Accordingly, the semiconductor device 100 demonstrated in this modified example is particularly effective when the light from the light source 110 travels in the x direction and is supplied to the pixels 106. In the case where the semiconductor device 100 is configured so that the light from the light emitting elements is applied toward the pixels 106 in the y direction, the light component in the y direction is applied onto the semiconductor film 136. However, since the light is also reflected at various angles in the semiconductor device 100 to result in a component travelling in the x direction, the light component travelling in the x direction can be blocked by the first gate electrode 132 and the second gate electrode 144. Therefore, it is possible to prevent or suppress the characteristic degradation of the transistor 130 caused by light.

### (3) Modified Example 3

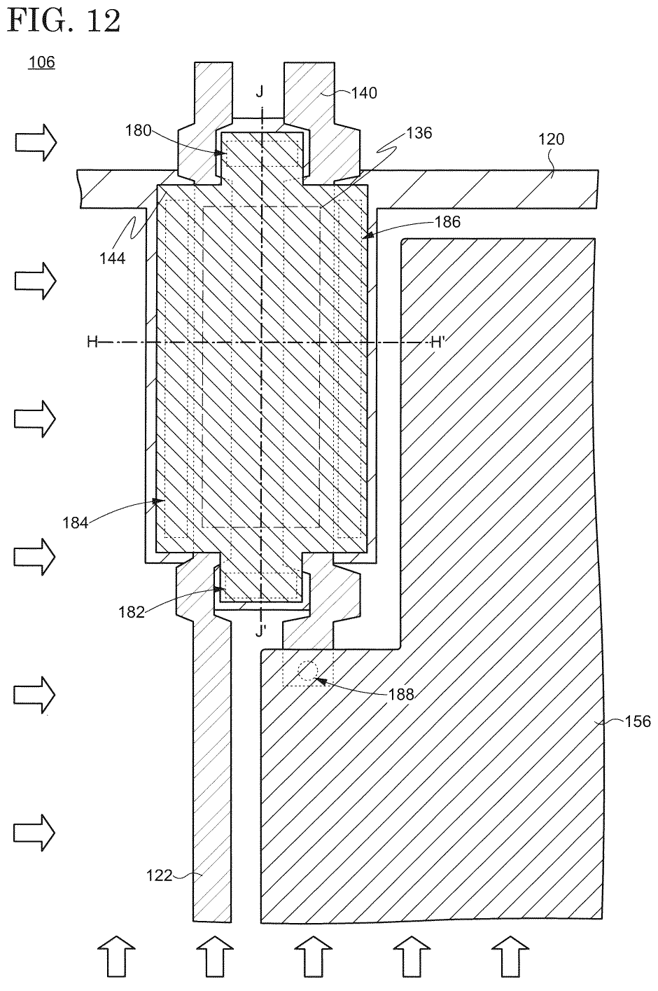

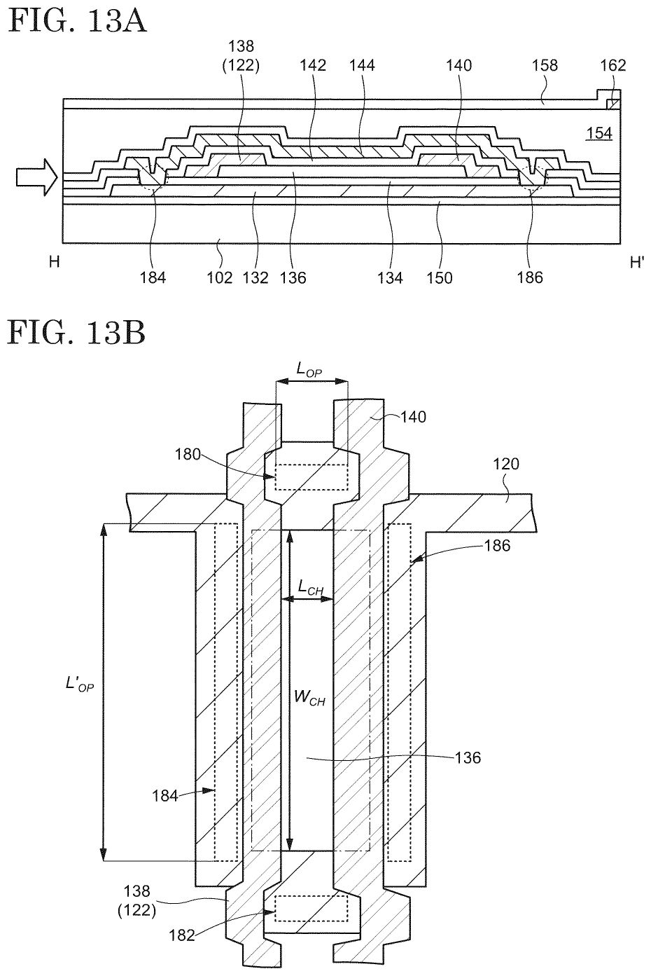

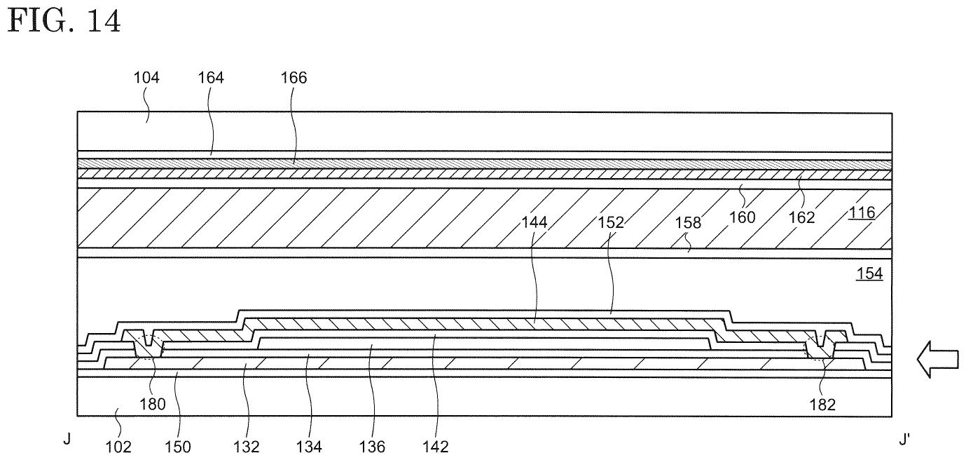

A schematic top view of the semiconductor device 100 of modified example 3 is shown in FIG. 12, and schematic views of cross sections along chain lines H-H′ and J-J′ in FIG. 12 are respectively shown in FIG. 13A and FIG. 14. In FIG. 13A, the components on the counter substrate 104 side from the liquid crystal layer 116 are omitted. As shown in these drawings, the semiconductor device 100 of this modified example may be further provided with the pair of openings 184 and 186 sandwiching the channel in the channel length direction as well as the pair of openings 180 and 182 sandwiching the channel in the channel width direction. The relationship between these openings 180, 182, 184, and 186 and the channel is the same as the relationship described above. That is, as shown in FIG. 13B which is an enlarged view of a part of FIG. 12 (the second gate electrode 144 is omitted), the length L_{OP} of each of the pair of openings 180 and 182 in the channel length width direction is larger than the channel length L_{CH} of the transistor 130. In addition, the whole of the channel of the transistor 130 is sandwiched between the pair of openings 180 and 182 in the channel width direction (FIG. 12) and overlaps the second gate electrode 144 in the normal direction of the substrate 102 (FIG. 14). Similarly, the length L′_{OP} of each of the pair of openings 184 and 186 in the channel width direction is larger than the channel width W_{CH} of the transistor 130. The whole of the channel of the transistor 130 is sandwiched between the pair of openings 184 and 186 in the channel length direction (FIG. 12) and overlaps the second gate electrode 144 in the normal direction of the substrate 102 (FIG. 13A). The terminal 138 (or the signal line 122) and the terminal 140 are also sandwiched between the pair of openings 180 and 182 in the channel width direction and between the pair of openings 184 and 186 in the channel length direction. In order to achieve the aforementioned relationship between the openings 180, 182, 184, and 186 and the channel, the portions of the signal line 122 and the terminals 140 sandwiching the openings 180 and 182 in the channel length direction may be bent as shown in FIG. 12 and FIG. 13B. Although not illustrated, the portions of the signal line 122 and the terminal 140 sandwiching the openings 184 and 186 in the channel width direction may also be bent.

By structuring the transistor 130 in this manner, it is possible to prevent the semiconductor film 136 from being irradiated not only with the light traveling in the y direction from the light source 110 but also with the light traveling in the x direction. Therefore, the degree of freedom in the arrangement of the light source 110 can be increased. In addition, even if the light from the light source 110 is reflected in the semiconductor device 100 and travels in various directions, degradation of the characteristics and reliability of the semiconductor device 100 caused by photo-degradation of the transistor 130 can be significantly reduced because the semiconductor film 136 is not irradiated with the light.

### (4) Modified Example 4

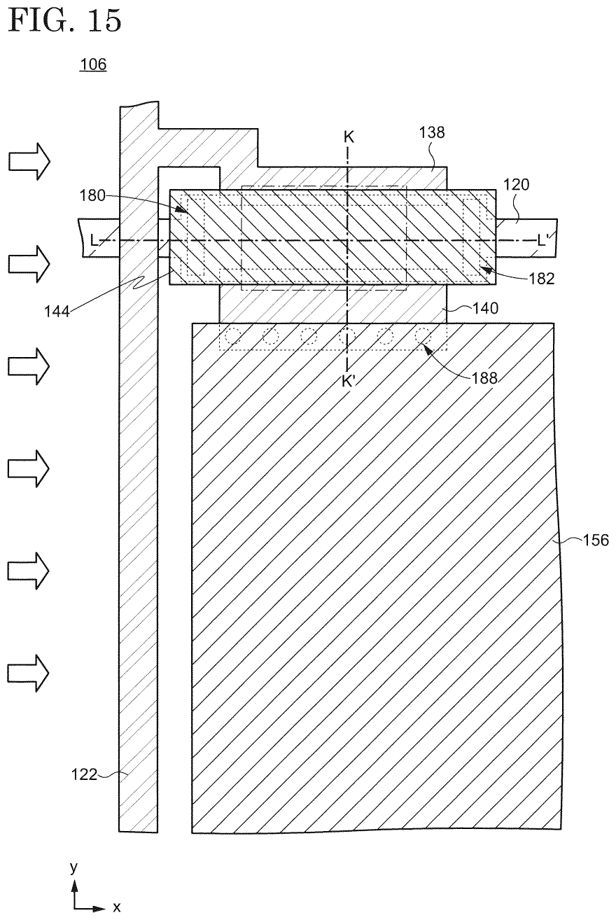

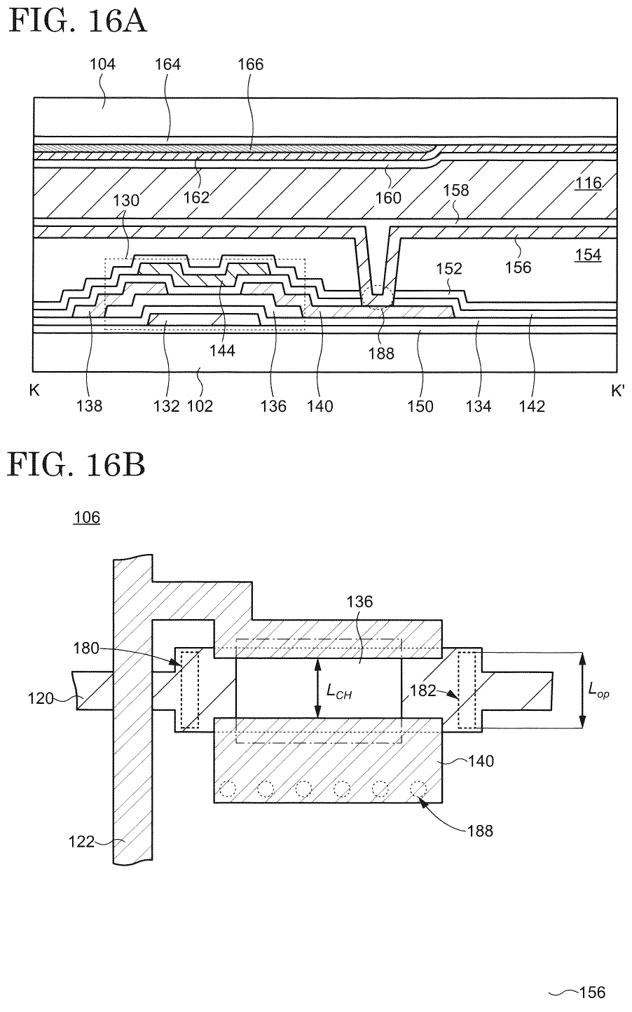

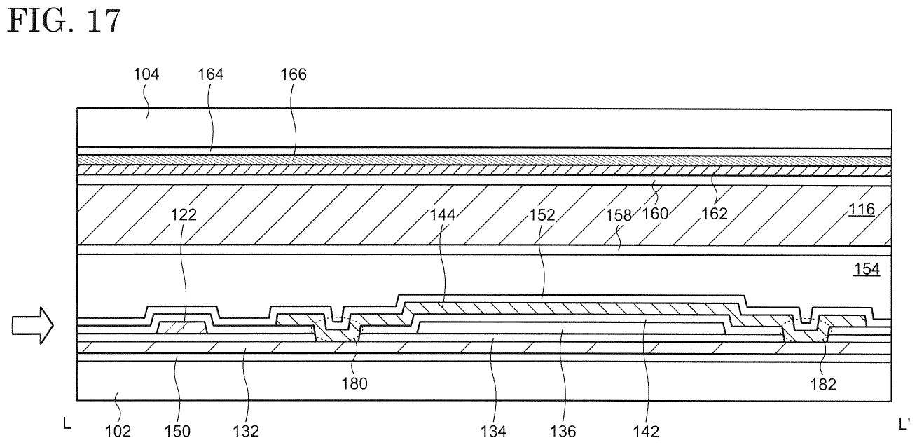

In the semiconductor device 100, the transistor 130 may be configured so that the channel length direction intersects the gate line 120 or is perpendicular to the gate line 120. Specifically, as shown in a schematic top view of FIG. 15 and schematic views of cross sections along chain lines K-K′ and L-L′ in FIG. 15 (FIG. 16A and FIG. 17), a branching structure is formed in the signal line 122, and the portion branched from the signal line 122 is used as the terminal 138. In addition, the terminal 140 is provided so as to overlap the terminal 138 in the direction parallel to the direction in which the signal line 122 extends along the plurality of pixels 106 (y direction). Meanwhile, the pair of openings 180 and 182 sandwiching the whole of the channel in the channel width direction is formed in the first gate insulating film 134 and the second gate insulating film 142, and the first gate electrode 132 and the second gate electrode 144 are electrically connected in these openings 180 and 182. Thus, the pair of openings 180 and 182 sandwich the channel in the direction parallel to the direction in which the gate line 120 extends. Although not illustrated, when the transistor 130 includes a plurality of semiconductor films 136 as the modified example 1, the plurality of semiconductor films 136 may be arranged parallel to the extending direction of the gate line 120.

An enlarged view of a part of FIG. 15 is shown in FIG. 16B. In FIG. 16B, the second gate electrode 144 is not illustrated for visibility. As shown in FIG. 16B, the length L_{OP} of each of the openings 180 and 182 in the channel length direction is larger than the channel length L_{CH}. The channel is sandwiched by the openings 180 and 182 in the channel width direction, and the whole of the channel further overlaps the second gate electrode 144 in the normal direction to the substrate 102. Moreover, the terminals 138 and 140 are sandwiched by the pair of openings 180 and 182 in the channel width direction. Therefore, as can be understood from FIG. 15 and FIG. 17, it is possible to effectively prevent the semiconductor film 136 from being irradiated with the light traveling in the x direction. Accordingly, the semiconductor device 100 demonstrated in this modified example is particularly effective in the case where the light from the light source 110 travels in the x direction and is supplied to the pixels 106.

### (5) Modified Example 5

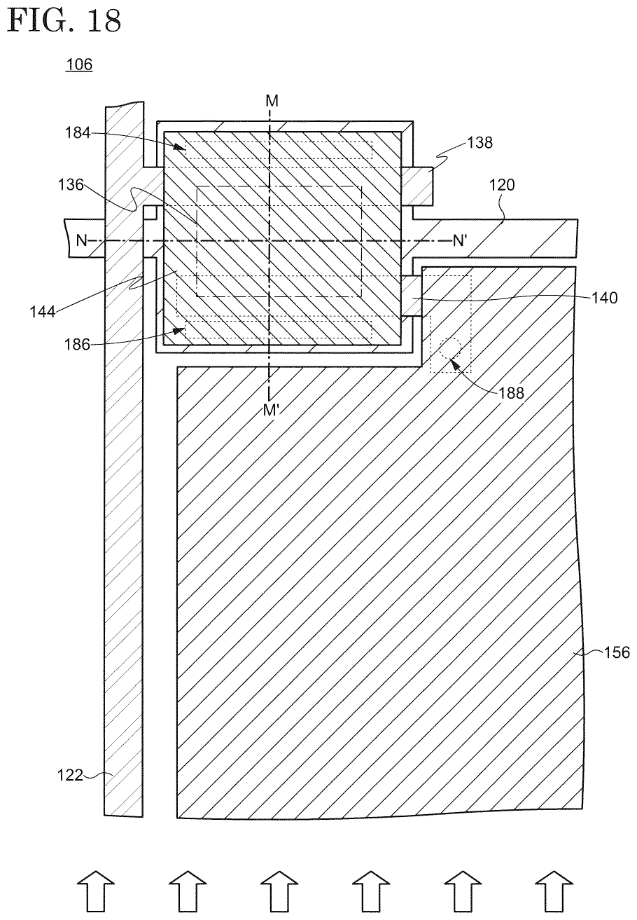

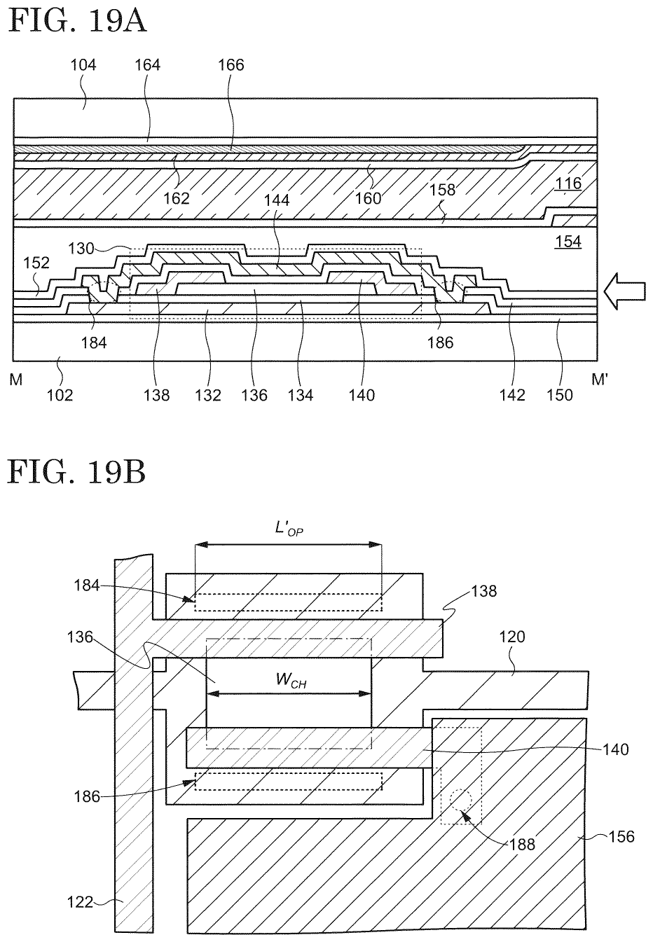

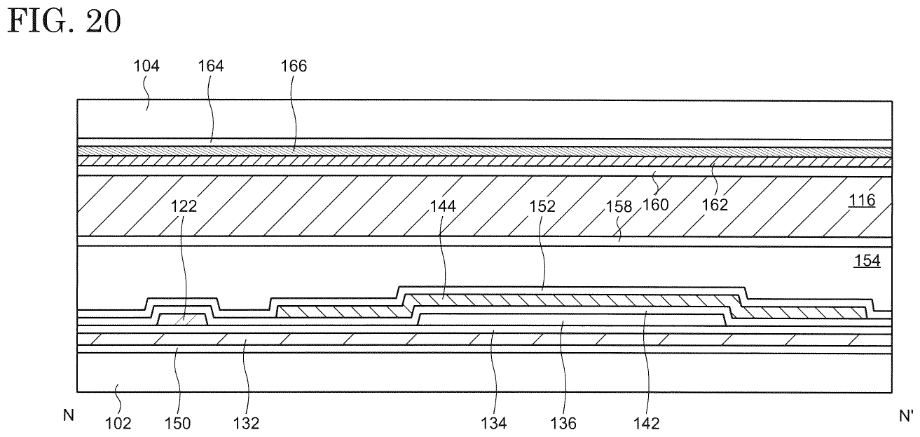

In contrast to the modified example 4, the semiconductor device 100 may be configured so that the pair of openings 184 and 186 sandwiching the whole of the channel in the channel length direction is formed in the first gate insulating film 134 and the second gate insulating film 142 and that the first gate electrode 132 and the second gate electrode 144 are electrically connected in these openings 184 and 186 as shown in a schematic top view of FIG. 18 and schematic views of cross sections along chain lines M-M′ and N-N′ in FIG. 18 (FIG. 19A and FIG. 20). In this case, the pair of openings 184 and 186 is arranged parallel to the channel length direction, i.e., the direction in which the signal line 122 extends along the plurality of pixels 106.

An enlarged view of a part of FIG. 18 is shown in FIG. 19B. In FIG. 19B, the second gate electrode 144 is not illustrated for visibility. As shown in FIG. 19B, the length L′_{OP} of each of the openings 184 and 186 in the channel width direction is larger than the channel width W_{CH}. The whole of the channel is sandwiched between the openings 184 and 186 in the channel length direction and also overlaps the second gate electrode 144 in the normal direction of the substrate 102. Furthermore, the terminals 138 and 140 are sandwiched by the openings 184 and 186 in the channel length direction. Therefore, as can be understood from FIG. 18 and FIG. 19A, it is possible to effectively prevent the semiconductor film 136 from being irradiated with the light traveling in the y direction.

### (6) Modified Example 6

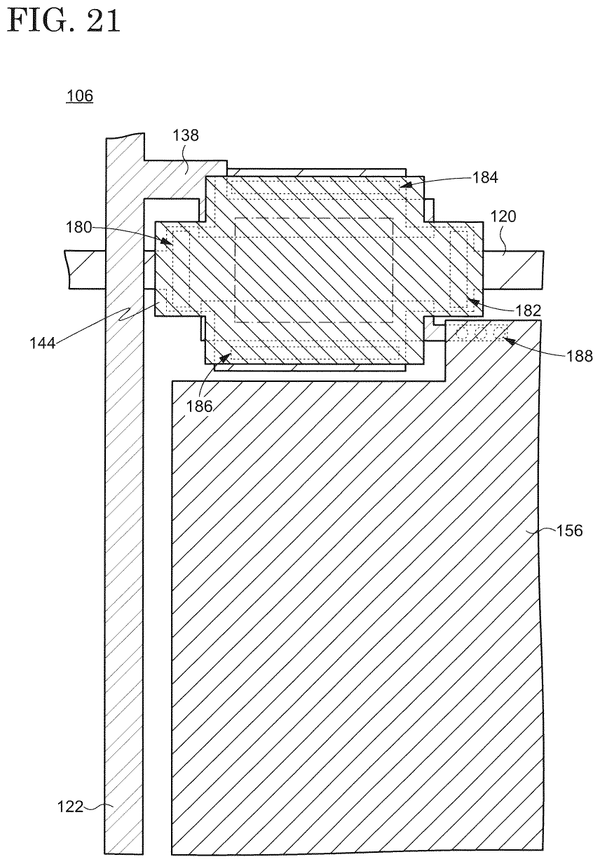

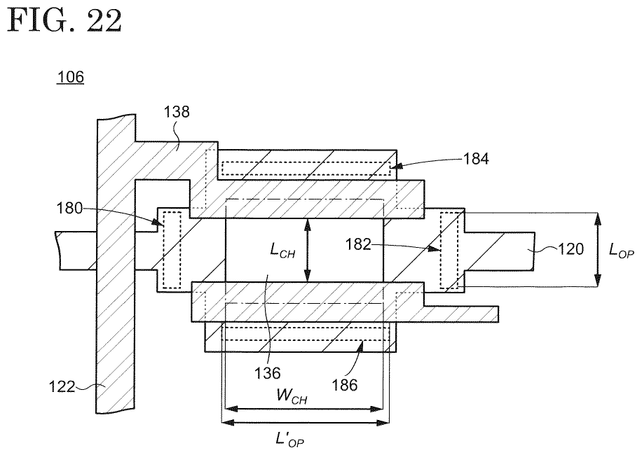

Furthermore, the openings 180, 182, 184 and 186 shown in the modified examples 4 and 5 may be simultaneously provided as shown in a schematic top view of FIG. 21 and in FIG. 22 which is an enlarged view of a part of FIG. 21 (the second gate electrode 144 is not illustrated in FIG. 22). Since the relationships between the semiconductor film 136, the channel, the pair of terminals 138 and 140, and the openings 180, 182, 184, and 186 with respect to size and arrangement are the same as those of the aforementioned modified examples 4 and 5 above, a detailed explanation is omitted.

### (7) Modified Example 7

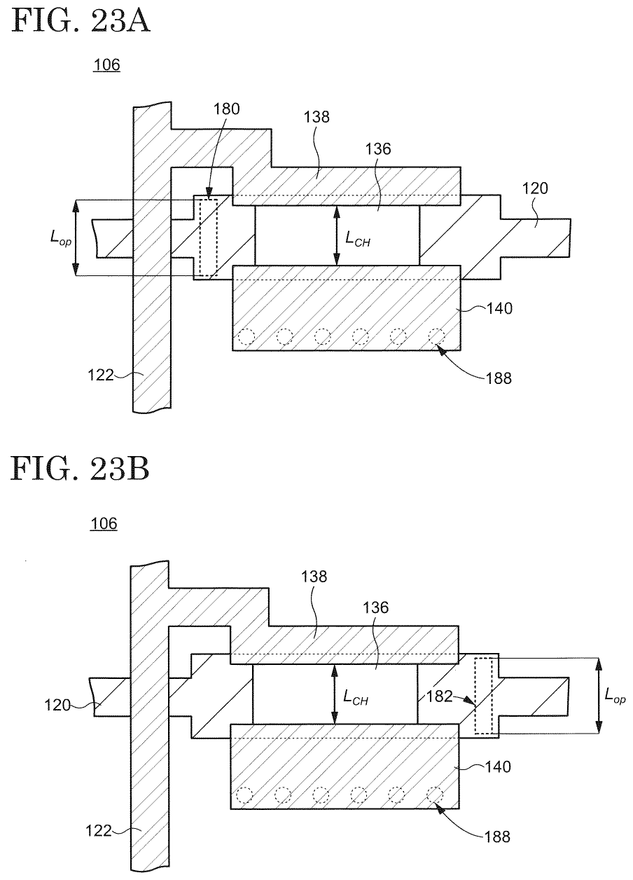

In all of the above-described examples, the electrical connection of the first gate electrode 132 and the second gate electrode 144 is performed by the pair of openings 180 and 182 and/or the pair of openings 184 and 186 sandwiching the semiconductor film 136 in the channel width direction and/or the channel length direction. However, it is not always necessary to perform the electrical connection of the first gate electrode 132 and the second gate electrode 144 with one pair of openings in the semiconductor device 100, and the electrical connection may be performed with the opening 180 or the opening 182 arranged on one side of the semiconductor film 136 in the channel width direction of the transistor 130 as shown in FIG. 23A and FIG. 23B (the second gate electrode 144 is not illustrated in these drawings), for example. In this case, each pixel 106 is preferably configured so that the opening 180 or the opening 182 is located between the light source 110 and the semiconductor film 136. The opening 180 or the opening 182 is formed so that the length L_{OP} of the opening 180 or the opening 182 in the channel length direction is larger than the channel length L_{CH} and that the whole of the channel overlaps the opening 180 or the opening 182 in the channel width direction, by which most of the light from the light source 110 is blocked, thereby suppressing the photo-degradation of the transistor 130. Although not illustrated, the electrical connection of the first gate electrode 132 and the second gate electrode 144 may be performed by the opening 184 or the opening 186 arranged on one side of the semiconductor film 136 in the channel length direction of the transistor 130.

As described above, in the semiconductor device 100 according to an embodiment of the invention, the light-shielding first gate electrode 132 and second gate electrode 144 respectively located under and over the semiconductor film 136 are electrically connected to each other. Moreover, the electrical connection of the first gate electrode 132 and the second gate electrode 144 may be performed by the pair of openings sandwiching the semiconductor film 136, and the pair of openings may be arranged to sandwich the whole of the channel of the transistor 130 including the semiconductor film 136 in the travelling direction of the light from the light source 110 in order to block the light from the light source 110 and prevent the semiconductor film from being irradiated with the light. Therefore, at the edge surface along the travelling direction of the light, the channel is confined by the first gate electrode 132 and the second gate electrode 144, and the channel is not irradiated with the light. As a result, photo-degradation of the transistor 130 is effectively suppressed. This feature contributes to the production of a highly reliable semiconductor device with suppressed characteristic degradation.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A semiconductor device comprising a transistor, the transistor comprising:
a gate line a part of which functions as a first gate electrode;
a first gate insulating film over the first gate electrode;
at least one semiconductor film located over the first gate insulating film and overlapping the first gate electrode;
a pair of terminals over and electrically connected to the at least one semiconductor film;
a second gate insulating film over the pair of terminals; and
a second gate electrode having a light-shielding property, located over the second gate insulating film, overlapping the first gate electrode and the at least one semiconductor film, and electrically connected to the first gate electrode through a first pair of openings formed in the first gate insulating film and the second gate insulating film,
wherein the first pair of openings sandwich the at least one semiconductor film in one of a channel width direction and a channel length direction of the transistor,
a length of the first pair of openings in the channel width direction is larger than a channel width of the transistor when the first pair of openings sandwich the at least one semiconductor film in the channel length direction, and
a length of the first pair of openings in the channel length direction is larger than a channel length of the transistor when the first pair of openings sandwich the at least one semiconductor film in the channel width direction.

2. The semiconductor device according to claim 1,
wherein the first pair of openings sandwich the pair of terminals in the channel length direction or the channel width direction.

3. The semiconductor device according to claim 1,
wherein the second gate electrode is further electrically connected to the first gate electrode through a second pair of openings formed in the first gate insulating film and the second gate insulating film, and
the second pair of openings sandwich the at least one semiconductor film in the other of the channel width direction and the channel length direction.

4. The semiconductor device according to claim 3,
wherein a length of the second pair of openings in the channel width direction is larger than the channel width of the transistor when the second pair of openings sandwich the at least one semiconductor film in the channel length direction, and
a length of the second pair of openings in the channel length direction is larger than the channel length of the transistor when the second pair of openings sandwich the at least one semiconductor film in the channel width direction.

5. The semiconductor device according to claim 1,
wherein the channel length direction is parallel to an extending direction of the gate line.

6. The semiconductor device according to claim 1,
wherein the channel length direction intersects an extending direction of the gate line.

7. The semiconductor device according to claim 1, further comprising a signal line over the first gate insulating film,
wherein one of the pair of terminals is a part of the signal line, is branched from the signal line, and is arranged parallel to the gate line.

8. The semiconductor device according to claim 1,
wherein the at least one semiconductor film includes a plurality of semiconductor films arranged perpendicular to an extending direction of the gate line.

9. The semiconductor device according to claim 1,
wherein the at least one semiconductor film includes a plurality of semiconductor films arranged parallel to an extending direction of the gate line.

10. The semiconductor device according to claim 1, further comprising:
a substrate under the transistor;
a counter substrate over the transistor; and
a light source exposed from the counter substrate in a normal direction of the substrate.

11. The semiconductor device according to claim 10,
wherein the light source comprises a plurality of light-emitting elements arranged in a direction parallel to an extending direction of the gate line.

12. The semiconductor device according to claim 10, further comprising a housing accommodating a part of the substrate, a part of the counter substrate, and the light source.

13. The semiconductor device according to claim 12,
wherein a bottom surface of the substrate and an upper surface of the counter substrate are exposed from the housing.

14. The semiconductor device according to claim 1, further comprising a liquid crystal element electrically connected to one of the pair of terminals.

15. The semiconductor device according to claim 1,
wherein the at least one semiconductor film includes an oxide semiconductor.
